(19) United States
(12) Patent Application Publication
(10) Pub. No.: US 2008/0290959 A1
(43) Pub. Date: Nov. 27, 2008

(54) MILLIMETER WAVE INTEGRATED CIRCUIT INTERCONNECTION SCHEME

(76) Inventors: Mohammed Ershad Ali, San Jose, CA (US); Rokhsareh Zarnaghi, Santa Clara, CA (US); Chinh Huy Doan, Santa Clara, CA (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/752,073

(22) Filed: May 22, 2007

(51) Int. Cl. H03H 7/38

(52) U.S. Cl. 333/32

(57) ABSTRACT

A millimeter-wave integrated circuit (IC) package is disclosed. The package includes a substrate having a plurality of layers and a vertical interconnection. The vertical interconnection comprises a shielded transition between the plurality of layers and a compensation structure to minimize the parasitic effect of the transition.

### FIELD OF INVENTION

An embodiment of the invention relates to integrated circuit packages, and more specifically, to millimeter wave integrated circuit packages.

### BACKGROUND

The success of millimeter wave radio for consumer applications, to a large extent, depends on the development of a low-cost packaging technology. Due to sensitivity of millimeter wave circuits to interconnection discontinuities and tolerances, high-precision packaging is implemented to ensure acceptable electrical performance. Accordingly, millimeter wave components use high-cost low-volume manufacturing processes for packaging. For example, millimeter wave components use a thin film process on a ceramic substrate and precision machining for input/output (I/O) feed-throughs.

Apart from cost, these conventional packages also limit the degree of integration that can be achieved in a package. Almost exclusively, radio frequency (RF) signal paths and interconnections in current millimeter wave packages are limited to planar circuits leading to modules with only a few RF channels or ports.

Low frequency and digital modules having a large number of components and functionalities often employ multilayer substrate technologies, such as High Temperature Co-Fired Ceramics (HTCC), Low Temperature Co-Fired Ceramics (LTCC) and laminate-based, which have matured enough over years to become available for volume manufacturing.

Very high density is achieved in these substrates by routing signals and even embedding components on multiple layers with numerous interconnections running vertically from one layer to the other. Making use of these substrate technologies for millimeter wave packaging would be an obvious choice for both reduction of cost and higher degree of integration. However, severe degradation in performance limits their applicability to higher frequencies.

Therefore, a millimeter wave package that implements vertical interconnection without performance degradation is desired.

### SUMMARY

According to one embodiment, a millimeter-wave integrated circuit (IC) package is disclosed. The package includes a substrate having multiple layers and an interconnection. The interconnection is a shielded transition between the layers and a compensation structure to reduce, and potentially minimize, the parasitic effect of the transition. In one embodiment, the compensation structure is built within the shielded transition, thereby making it possible for the interconnection to work at millimeter wave frequencies.

According to another embodiment, a system is disclosed. The system includes a radio frequency IC (RFIC) and a millimeter-wave integrated circuit (IC) package mounted to the RFIC. The package includes a substrate having layers, where flip-chip pads are mounted on a first substrate layer to receive millimeter-wave signals from the RFIC and a interconnection for each of the signals. The interconnection providing a shielded transition between the layers and a compensation structure to reduce, and potentially minimize, the parasitic effect of the transition.

### DESCRIPTION OF THE DRAWINGS

The invention may be best understood by referring to the following description and accompanying drawings that are used to illustrate embodiments of the invention. In the drawings:

FIG. 1 illustrates one embodiment of a millimeter wave integrated circuit package;

FIG. 2 illustrates one embodiment of a radio frequency integrated circuit bonded to a millimeter wave integrated circuit package; and

FIGS. 3a and 3b illustrate performance results for a millimeter wave integrated circuit package.

### DETAILED DESCRIPTION

A system for vertical interconnection in a multilayer substrate package with reduced, and potentially minimal, degradation in signal quality at millimeter wave frequencies is described. According to one embodiment, the vertical interconnection includes a shielded via transition between layers with passive compensation structures as part of the transition. In a further embodiment, the transition is placed at or very near flip-chip pads where an RF integrated circuit (RFIC) millimeter wave input/output (I/O) port would be located. The compensation that is built into the transition structure alleviates the adverse distributed parasitic effects of the layer-transition and the flip-chip bump interface. That is, in one embodiment, the compensation structure is built within the shielded transition, thereby making it possible for the interconnection to work at millimeter wave frequencies.

In the following description, numerous details are set forth. It will be apparent, however, to one skilled in the art that embodiments of the present invention may be practiced without these specific details. In other instances, well-known structures, devices, and techniques have not been shown in detail, in order to avoid obscuring the understanding of the description. The description is thus to be regarded as illustrative instead of limiting.

Reference in the specification to “one embodiment” or “an embodiment” means that a particular feature, structure, or characteristic described in connection with the embodiment is included in at least an embodiment of the invention. The appearances of the phrase “in one embodiment” in various places in the specification are not necessarily all referring to the same embodiment.

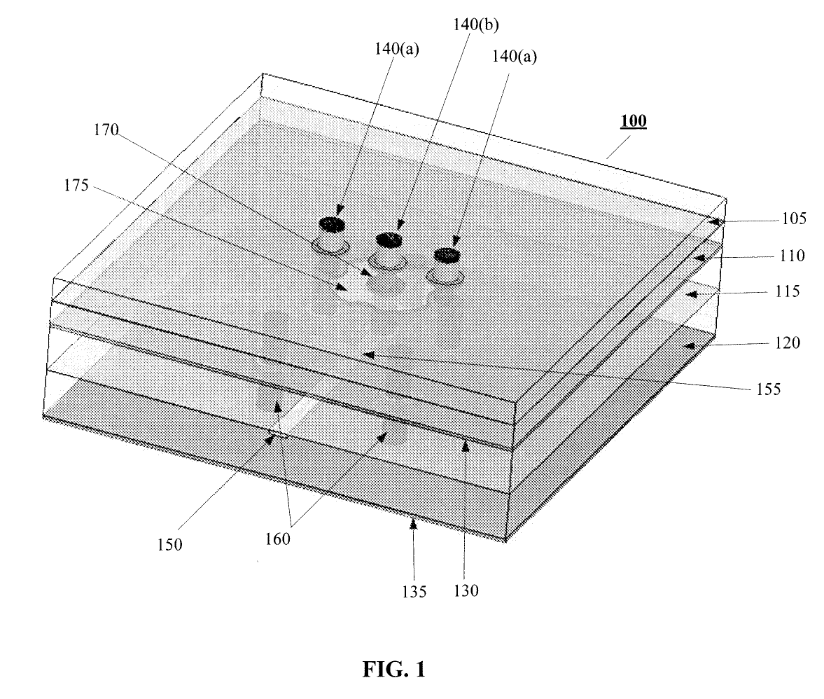

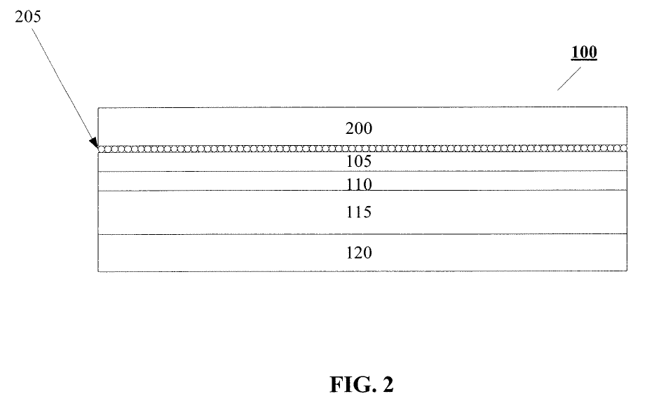

FIG. 1 illustrates one embodiment of a millimeter wave integrated circuit package 100. Package 100 includes layer 105, layer 110, layer 115 and layer 120. In one embodiment, layers 105, 110, 115 and 120 are four dielectric layers of a six-layer HTCC substrate. Two unused layers below layer 120 are not shown (to avoid obscuring the present invention). In a further embodiment, an RFIC is flip-chip bonded to the HTCC substrate at layer 105. FIG. 2 illustrates one embodiment of an RFIC 200 bonded to package 100 via flip-chip bumps 205 (without the ground planes shown).

Referring back to FIG. 1, package 100 also includes ground planes 130 and 135, flip-chip pad 140, signal trace 150, compensation structure 155, ground shield vias 160, layer transition vias 170 and ground plane opening 175. Ground shield vias 160 include all the vias that connect the two ground planes 130 and 135. Flip-chip pads 140 include ground pads 140(a) and a signal pad 140(b). Note that there can be any number of ground pads in 140(a), although only two are shown in FIG. 1. According to one embodiment, a millimeter wave signal available at the flip-chip pad 140(b) is connected to strip-line signal trace 150 in a multilayer substrate using a vertical interconnection system. Flip-chip pads 140 are coupled to layer transition vias 170 that traverse dielectric layers 105, 110 and 115 and ground plane 130 to get to the layer 120 (e.g., strip-line layer). In one embodiment, the total via length is approximately 400 microns. In one embodiment, the total via length is a function of number of layers traversed and their thicknesses.

Ground shield vias 160 are included in the layers to suppress higher-order modes. Ground plane opening 175 is an opening in ground plane 130 around the signal pad 140 via. In one embodiment, the opening size of plane opening 175 and the diameters and pitch of pads 140 and via 170 are designed according to standard design rules of a low-cost volume manufacturable HTCC process.

Using the vertical interconnection scheme, the millimeter wave signal from RFIC 200 is routed through to signal trace 150 on an inner metal layer of the substrate. For a strip-line design, there is a trace only for the signal pad 140(b), the other pads, 140(a), are connected to the ground planes. As the millimeter wave signal propagates from RFIC 200 through the flip-chip bumps and layer transition vias 170, the signal encounters distributed parasitics, as well as changes in its modal field patterns. If not compensated in an appropriate manner, there would be unwanted resonances, higher-order mode excitation and scattering due to radiation. The net results of these degradations may cause almost no transmission of signals through an uncompensated interconnection. The length of the overall transition and the size of the ground opening are a significant fraction of the guided wavelength at millimeter waves. The complicated nature of the discontinuity makes it difficult to compensate for the signal degradation in a traditional manner, where the matching networks are placed away from the transition.

Thus in one embodiment, a compensation network is integrated into the layer transition structure. In such an embodiment, the placement, size and shape of the compensation network are determined through a modeling process. In a further embodiment, the modeling process includes a method of optimization that makes use of a three-dimensional (3D) electromagnetic tool (e.g., a High Frequency Structure Simulator (HFSS)), and a circuit simulator (e.g., an advanced design system (ADS)).

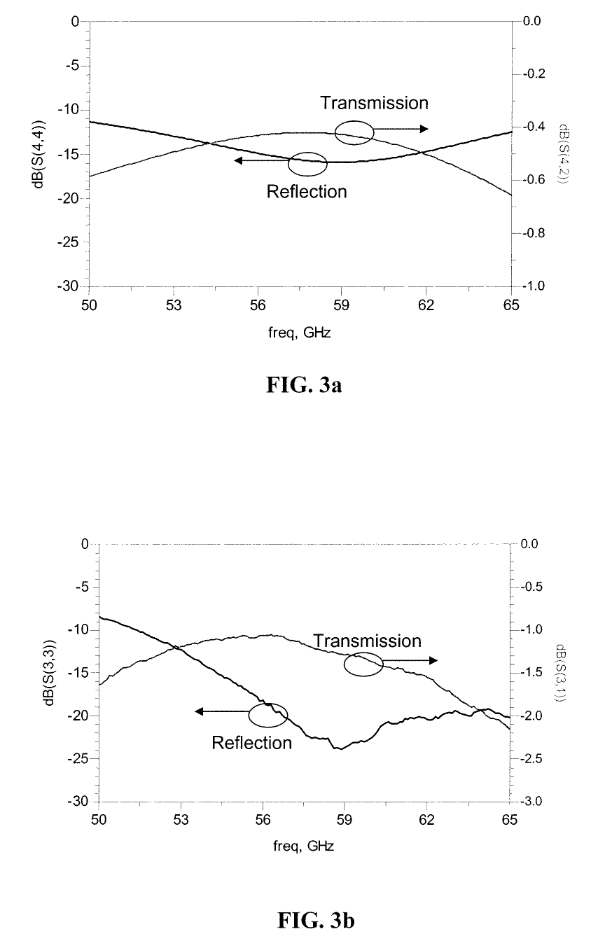

FIGS. 3a and 3b illustrate performance results for a millimeter wave integrated circuit package. FIG. 3a illustrates simulation results of a single vertical interconnection, as shown in FIG. 1. The transmission loss is within 0.5 dB and the reflection is below −10 dB across 50-65 GHz, the designed band of operation.

According to one embodiment, multiple interconnections may be closely spaced to enable the system to be suitable for a package including a multitude of millimeter wave ports. FIG. 3b illustrates measurement results where two vertical interconnections are connected by a small length of strip-line. As shown in FIGS. 3a and 3b, the average transmission loss is ˜1.5 dB and the reflection is of relatively high-quality across the band.

The above-described system combines layer transition and a flip-chip interface with built-in compensation to enable vertical interconnection to be compact and suitable for use in a package with a multitude of millimeter wave ports.

It should be appreciated that in the foregoing description of exemplary embodiments of the invention, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

The foregoing description has been directed to specific embodiments. It will be apparent to those with ordinary skill in the art that modifications may be made to the described embodiments, with the attainment of all or some of the advantages. Therefore, it is the object of the appended claims to cover all such variations and modifications as come within the spirit and scope of the invention.

What is claimed is:

1. A millimeter-wave integrated circuit (IC) package comprising:
a substrate having a plurality of layers; and
an interconnection, having:
a shielded transition between the plurality of layers; and
a compensation structure to reduce the parasitic effect of the transition.

2. The package of claim 1 further comprising:
a flip-chip pad mounted on a first substrate layer of the plurality of layers to receive a millimeter-wave signal from a radio frequency IC (RFIC); and
a trace embedded in a second substrate layer to couple the millimeter-wave signal from the flip-chip pad.

3. The package of claim 2 wherein the interconnection comprises transition vias to couple the millimeter-wave signal from the flip-chip pad to the trace through one or more substrate layers between the first and second layers.

4. The package of claim 2 further comprising ground shield vias to suppress high order modal field patterns.

5. The package of claim 4 further comprising a ground plane enclosing the signal trace.

6. A system comprising:
a radio frequency IC (RFIC);
a millimeter-wave integrated circuit (IC) package mounted to the RFIC, comprising:
a plurality of substrate layers;
a plurality of flip-chip pads mounted on a first of the plurality of substrate layers to receive millimeter-wave signals from the RFIC; and
an interconnection coupled to the flip-chip pads, having:
a shielded transition between the plurality of layers; and
a compensation structure to reduce the parasitic effect of the transition.

7. The system of claim 6 further comprising a trace embedded in one of the substrate layers to couple one of the millimeter-wave signals from one of the flip-chip pads.

8. The system of claim 7 wherein the interconnection comprises transition vias to couple the one millimeter-wave signal from the one flip-chip pad to the trace through multiple substrate layers.
